(19) United States
(12) Patent Application Publication
(10) Pub. No.: US 2002/0074640 A1
(43) Pub. Date: Jun. 20, 2002

(54) Semiconductor test socket having pogo-pin contacts

(76) Inventor: Rodolfo I. Gamboa, Baguio City (PH)

Correspondence Address: J. Dennis Moore, Texas Instruments Incorporated, M/S 3999, PO Box 655474, Dallas, TX, 75265, US

(21) Appl. No.: 09/735,668

(22) Filed: Dec. 20, 2000

(51) Int. Cl. H01L 23/48

(52) U.S. Cl. 257/690

(57) ABSTRACT

A preferred embodiment test socket comprises a body for receiving a semiconductor device having a plurality of pins, the body having an integrally formed guidepost and a chamfered impact base and a floating base disposed within the body. The floating base coming into contact with the semiconductor device and provides movement of the semiconductor device to alleviate unwanted pressure from the plurality of pins. The test socket further comprises a plurality of pogo-pins adjacent to one another, each pogo-pin comprising a cylindrical chamber and a plunger having a crown top at both ends, one end for directly contacting a pin of the semiconductor device and the other end for contacting external test equipment and a back panel removably attached to the body.

### FIELD OF INVENTION

This invention relates to semiconductor test socket and more particularly to a semiconductor test socket utilizing pogo-pin contacts.

### BACKGROUND OF THE INVENTION

The challenge for lasting, good contacting, and reliable test sockets has vexed socket manufacturers and designers for years. Poor test socket contacting has resulted in an increase of scrapped semiconductor devices in the semiconductor industry due to mistest of the device. Mistested devices are basically good devices that were scrapped due to poor socket contact during testing. The challenge for higher throughput demands more initiatives to solve the problem of poor contacting.

While the problem of mistested devices may occur during the testing of any device, mistest is particularly prevalent for Quad Flat Packages (QFPs). FIG. 1 illustrates a quad flat package 20. Quad Flat Packages are high-density, surface-mount packages with leads 22 protruding on all four sides of the package 20. The QFP has the most variations of any package type and must be carefully specified for adapters and sockets. The shape of the leads QFP and the existing methods for contacting these leads may be the source of many scrapped devices due to mistest.

There are many possible causes of mistest including dirt and oxides that accumulate on the device pin and socket pin. Due to the smooth surface of many prior art sockets (Shown in FIG. 2a), the accumulated dirt and oxides cannot be penetrated to initiate contact. Another cause of mistest is excessive insertion force as shown in FIG. 2b. The excessive force will push the contact pin down to its fully compressed position while causing only a part of the device pin to make a contact. Misalignment will also result in mistest, as misalignment causes a part to be damaged, lost or false tested.

Thus what is needed is a socket design which will eliminate mistest resulting from dirt and oxides, excessive insertion force and misalignment of the contacts.

### SUMMARY OF THE INVENTION

These and other problems are generally solved or circumvented, and technical advantages are generally achieved, by preferred embodiments of the present invention that utilize pogo-pins in a semiconductor test socket.

A preferred embodiment test socket comprises a body for receiving a semiconductor device having a plurality of pins. The body has an integrally formed guidepost, a chamfered impact base, and a floating base. The floating base is designed to come into contact with the semiconductor device and provides movement of the semiconductor device to alleviate unwanted pressure from the plurality of pins. The socket further comprises a plurality of pogo-pins adjacent to one another and a back panel removeably attached to the body. Each pogo-pin has a cylindrical chamber and a plunger with a crown top at both ends, one end for directly contacting a pin of the semiconductor device and the other end for contacting external test equipment.

A preferred embodiment semiconductor device comprises a package, an integrated circuit disposed within the package, and a plurality of pins each having a series of contact marks. Each set of contact marks are of substantially the same pattern and spaced by a pre-determined pitch.

One advantage of a preferred embodiment of the present invention is that the dirt and oxides which have accumulated on the surface of the socket can be penetrated to initiate contact between the pins of the semiconductor device and the test socket.

Another advantage of certain aspects of the present invention is that excessive insertion force will not cause the contact pin of the test socket to over extend causing only partial contact between the pin of the semiconductor device and the test equipment. The adjacent pogo-pins adjust their lengths with respect to the pressure applied while maintaining a good contact whereas a chamfered impact base of the socket body prevents any damage to the pogo-pins inherent to the process.

Yet another advantage of a preferred embodiment of the present invention is that it can reduce the possibility of misalignment. The slant grooved-guide posts are specifically designed to align all four corners of the QFP.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The above features of the present invention will be more clearly understood from consideration of the following descriptions in connection with the accompanying drawings in which:

FIG. 1 shows a Quad Flat Package.

FIG. 2a and 2b illustrate the problems of mistested prior art test socket;

FIG. 3 illustrates a variety of pogo-pins;

FIG. 4 is a top view of the preferred embodiment of a test socket of the present invention;

FIG. 5a is a cross section of the preferred embodiment of the present invention;

FIG. 5b illustrates an exploded view of FIG. 5a;

FIG. 6 illustrates the pogo-pin utilized by the preferred embodiment of the present invention;

FIG. 7 is another cross section of the preferred embodiment of the present invention implementing the semiconductor device with highlights on the slant-grooved guide post and chamfered impact base;

FIGS. 8a and 8b illustrate visual contact marks of the present invention and the prior art; and

FIG. 9 illustrates a semiconductor device having the visual contact marks of the present invention.

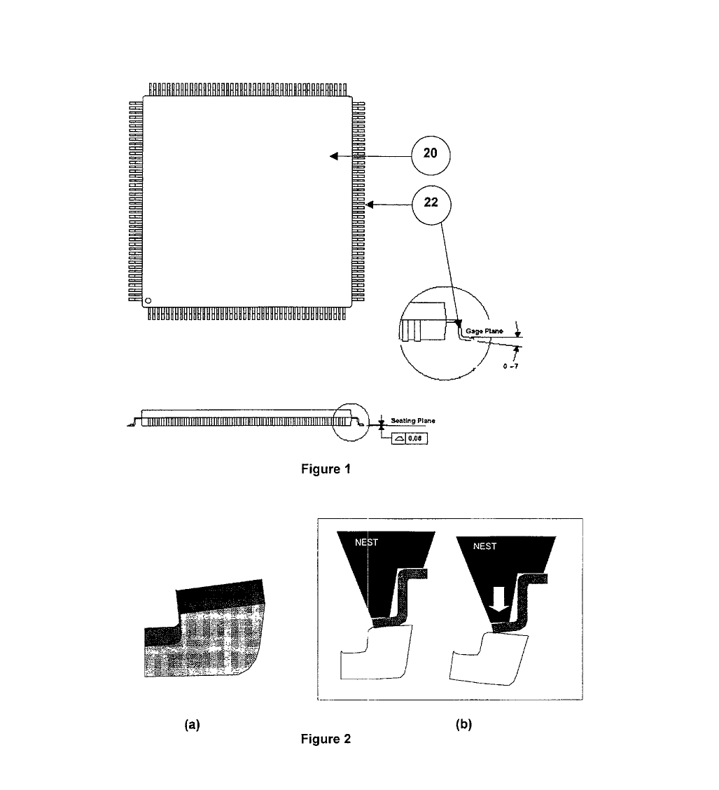

### DETAILED DESCRIPTION OF THE PRESENT INVENTION

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

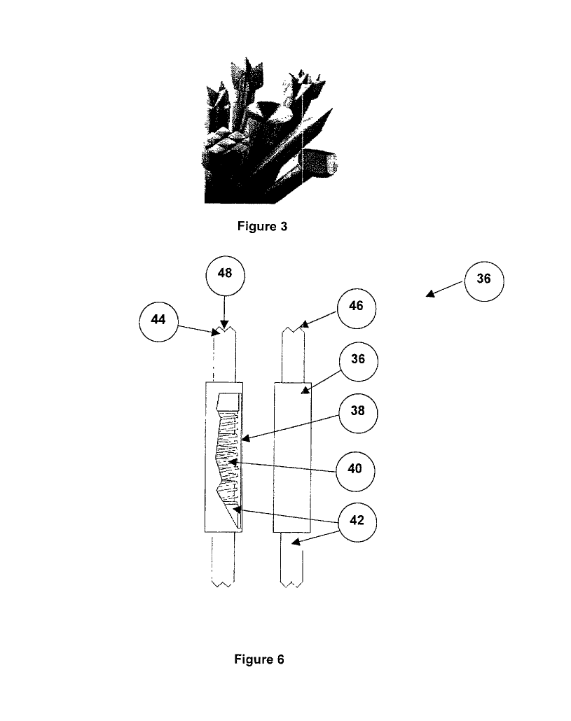

FIG. 3 illustrates a variety of pogo-pin designs. The pogo-pins were designed for bed of nails printed circuit board testing, but can be utilized in any application requiring a contact in compliance with flat leads such as those found in QFPs. While pogo-pins have been used in prior art BGA test sockets, they have not been implemented in the manner disclosed herein which is useful in applications requiring testing of QFPs. While any of the pogo-pin designs of FIG. 3 can be used, the preferred embodiment of the present invention provides an efficient design utilizes a pogo-pin having a crown top.

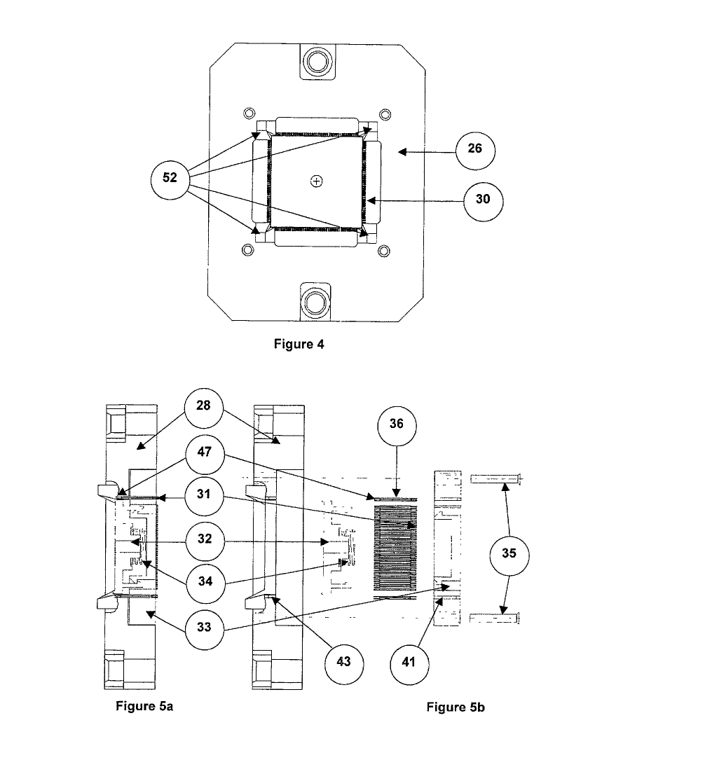

The preferred embodiment of a test socket 26 of the present invention is shown in FIG. 4. The test socket 26 comprises a body 28 for receiving the semiconductor device, a plurality of pogo-pins 30, and a series of guide posts 50. The body 28 has a chamfered impact base 39 as highlighted in FIG. 7. The chamfered impact base 39 supports the pin of the semiconductor device on strong impact to prevent damage or bending of the pin. The chamfered impact base generally extends at an angle between zero and seven degrees below the horizontal axis of the crown top of the plurality of pogo pins 30. The angle is preferably seven degrees to provide the best tolerance of any excessive force. Around the impact base are thru holes 37 for the pogo-pins 30. The number of pogo-pins 30 and thru holes 37 equal the number of pins in the semiconductor device to be tested.

As shown in the cross-sectional view of FIG. 5a, within the body 28 is a floating base 32 which the semiconductor device contacts during the testing procedure. The floating base 32 comprises a spring 34 made of a metallic material and a base component 70 comprised of a plastic material. The base component 70 is substantially square in shape and has a cylindrical shaft underneath to receive the spring 34. Although used by prior art test sockets, the floating base of the prior art was not designed in the manner disclosed herein, which is used in parallel with pogo-pins. The floating base 32 of the present invention is designed to allow the semiconductor device to move downward as needed when pressure is provided to press the pins of the semiconductor device into contact with the pogo-pins 30. The downward movement of the semiconductor device alleviates some of the pressure from the pins which could break if too much pressure is applied to the semiconductor device. The spring 34 which supports the floating base 32, allows the floating base 32 to move downward. The downward force which compresses the spring 34 is generally provided by a nest (not shown).

As shown in FIG. 5b, the preferred embodiment of the present invention utilizes a plurality of pogo-pins 36 which are adjacent to each other in order to make contact with the pins of the semiconductor device. The pogo-pins 36 are firmly supported by a back panel 33 that can be fastened to the body 28 by any suitable means, but preferably screws 35. The back panel 33 is designed to have through holes 41 to position the lower part of the pogo-pins in place. The body 28 also has openings 43 to support the upper part of the pogo-pins 36.

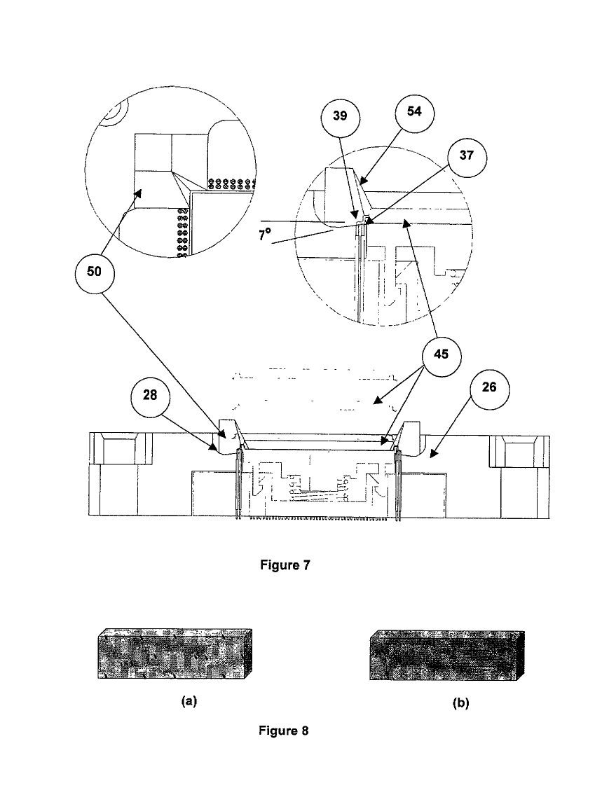

The pogo-pin 36, as shown in FIG. 6 will operate as the contact point for the pins of the semiconductor device and comprises a chamber 38, an internal spring 40, and plungers 42 at each end of the chamber 38. The pogo-pin chamber 38 and plungers 42 may have any shape, but are both, preferably, substantially cylindrical in shape. The chamber 38 houses the internal spring 40. The plungers 42 include a crown 44. The contact point 47 illustrated in FIG. 5b is the crown of each of the plungers 42. The internal spring 40 allows the pogo-pin 36 to adjust itself evenly with the pressure applied to protect the pins from breakage if too much pressure is applied. The crown 44 has four pointed ends 46 and a series of crevices 48 in which the pin is to contact. The pointed ends 46 generally have a pitch in the range of 0.15 to 0.18 millimeters. While crown 44 may contain two or more pointed ends 46, the crown will preferably have four pointed ends 46 which aptly penetrate any oxide and/or dirt that have accumulated on the crown 44 to provide a good contact between the semiconductor pins and the test socket.

FIG. 7 is another cross sectional view the preferred embodiment of the present invention implementing a semiconductor device 45. As the semiconductor device 45 is pressed against the test socket 26, the series of guide posts 50, which are integrally formed within the body 28, help to ensure that the pins of the semiconductor device 45 are correctly aligned against the pogo-pins 36 to facilitate a good contact. In the prior art, the series of guideposts 50 are implemented as part of the floating base 32. Thus if the nest hits the series of guideposts 50 during testing, the floating base is pushed down without the semiconductor device having made sufficient contact with the pogo-pins 36. In the preferred embodiment of the present invention, if the nest hits the series of guideposts 50, it does not result in the floating base 32 being pushed down. Only the semiconductor device is pushed to the desired position. The series of guideposts 50 are located at each corner 52 (shown in FIG. 4) of the test socket 26 and has a slanted groove 54 which further facilitates proper alignment of the semiconductor device on the floating base 32.

The pogo-pins 36 also ensure that an excessive pressing force will not result in mistest. As shown in FIG. 2b, the prior art test socket pins would bend downward when an excessive pressing force was exerted on the prior art socket pins. This resulted in only partial contact with the pins of the semiconductor device. However, the pogo-pins 36 of the present invention will adjust with respect to the pressure exerted and maintain the contact on the length of the pins of the semiconductor device.

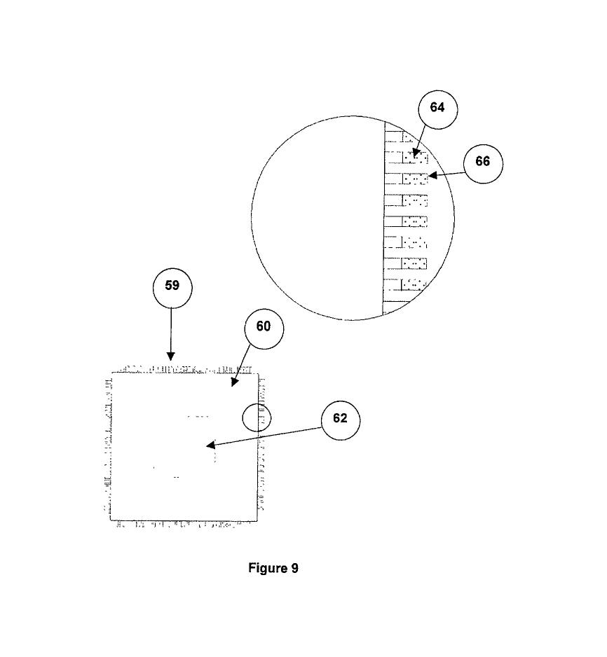

While the present invention provides a means to decrease problems with mistest, it also provides an indicator for verification that proper contact was made between the pins of the semiconductor device and the test socket. When the crown 48 of the pogo-pins 36 comes into contact with the pins, unique visual contact marks as shown in FIG. 8a are left. This provides a visual indication that sufficient contact was made. This visual indication is in contrast to the prior art which creates a visual means of detecting if contact was made but does not indicate that sufficient contact was made as the pins of the semiconductor device may have only made partial contact as shown in FIG. 2b. The visual means of detecting contact of the prior art is generally scratch marks as shown in FIG. 8b. The unique contact marks of the present invention will result in a semiconductor device as shown in FIG. 9.

The semiconductor device 59 comprises a package 60 in which is disposed an integrated circuit 62 and a plurality of pins 64. Each of the pins 64 includes a set of contact marks 66 having substantially the same pattern. The pattern is the pattern of the pointed ends of the crown portion of the pogo-pins.

The method of using the preferred embodiment of the present invention comprises providing the preferred embodiment of the test socket 26, aligning the semiconductor device within the body by utilizing a series of guide posts 50, applying a pressure which brings the plurality of pins of the semiconductor device into good contact with the pogo-pins, and testing the semiconductor device. Thus, the present invention provides for penetration of dirt and oxides and a visual indicator, prevents mistesting by excessive insertion force, and produces a self-aligning test socket 26 by utilizing a unique guidepost 54.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A test socket for a semiconductor device having a plurality of pins, the test socket comprising:
a body for receiving a semiconductor device, the body having an integrally formed guidepost and a chamfered impact base;
a floating base disposed within the body, floating base coming into contact with the semiconductor device and providing movement of the semiconductor device to alleviate unwanted pressure from the plurality of pins;
a plurality of pogo-pins adjacent to one another, each pogo-pin comprising a cylindrical chamber and a plunger having a crown top at both ends, one end for directly contacting a pin of the semiconductor device and the other end for contacting external test equipment; and
a back panel removably attached to the body.

2. The test socket of claim 1 wherein the semiconductor device is Quad Flat Pack (QFP).

3. The test socket of claim 1 wherein the guide post comprises:
a first portion having a substantially rectangular shape, a top edge, and a first side; and
a second portion having a substantially triangular shape and having a first leg at a ninety degree angle to a second leg, the first leg integrally connected to the first portion along its first side.

4. The test socket of claim 1 wherein the chamfered impact base extends at an angle between zero and seven degrees below the horizontal axis of the crown top of the plurality of pogo pins.

5. The socket of claim 1 wherein the floating base comprises:
a spring comprised of metallic material; and
a base component comprised of plastic material, the base component substantially square in shape and having a cylindrical shaft underneath to receive the spring.

6. The test socket of claim 5 wherein the metallic material is a steel alloy.

7. The test socket of claim 1 wherein the back panel has through holes to receive the plurality of pogo-pins.

8. The test socket of claim 7 wherein screws are utilized to attach the back panel to the body.

9. The test socket of claim 1 wherein the plurality of pogo-pins each comprise a plunger and an internal spring exerting a force upon the plunger at both ends.

10. The test socket of claim 9 wherein the internal spring of each pogo-pin is disposed within the chamber of the pogo-pin.

11. The test socket of claim 1 wherein the plurality of pogo-pins are comprised of metallic material.

12. The test socket of claim 1 wherein the plurality of pogo-pins are plated with a metallic material.

13. The test socket of claim 11 wherein the metallic material is gold.

14. The test socket of claim 1 wherein the plurality of pogo-pins are sets of two pogo-pins for contacting each pin of the semiconductor device.

15. The test socket of claim 1 wherein the guidepost includes a slanted groove for ensuring proper alignment of the semiconductor device.

16. The test socket of claim 1 wherein the crown of the each of the plurality of pogo-pins comprises four pointed ends and a series of crevices for making contact with the pins of the semiconductor device.

17. The test socket of claim 16 wherein the four pointed ends have a maximum pitch of 0.14 mm.

18. A semiconductor device comprising:
a package;
an integrated circuit disposed within the package; and
a plurality of pins each having a series of contact marks, each set of contact marks being of substantially the same pattern and spaced by a predetermined pitch.

19. The semiconductor device of claim 17 wherein a series of sets of contact marks result from the testing of the semiconductor device in a test socket comprising a plurality of pogo-pins having a crown portion with pointed ends for directly contacting the plurality of the semiconductor device, the pointed ends having the predetermined pitch.

20. The semiconductor device of claim 20 wherein the predetermined pitch is less or equal to 0.14 mm.

21. A method of testing a semiconductor device having a plurality of pins, the method comprising:
providing a test socket having a body for receiving a semiconductor device, the test socket including a plurality of guidepost integrally formed within the body and a plurality of pogo-pins adjacent to one another for directly contacting the plurality of pins;
aligning the semiconductor device within the body utilizing the guide posts;
applying a pressure which brings the plurality of semiconductor device pins into contact with the plurality of pogo-pins; and
testing the semiconductor device.

22. The method of claim 21 wherein each of the plurality of pogo-pins comprises an internal spring disposed in a chamber, the internal spring utilized for evenly distributing pressure on the plurality of pogo-pins.
